(19) United States
(12) Patent Application Publication
(10) Pub. No.: US 2024/0096845 A1
(43) Pub. Date: Mar. 21, 2024

(54) CIRCUIT PACKAGES WITH BUMP INTERCONNECT POLYMER SURROUND AND METHOD OF MANUFACTURE

(71) Applicant: QUALCOMM Incorporated, San Diego, CA (US)

(72) Inventors: Yangyang Sun, San Diego, CA (US); Dongming He, San Diego, CA (US); Yujen Chen, Taichung (TW)

(21) Appl. No.: 17/934,023

(22) Filed: Sep. 21, 2022

(51) Int. Cl. H01L 23/00; H01L 21/56; H01L 23/31; H01L 25/065

(52) U.S. Cl. CPC H01L 24/73; H01L 21/563; H01L 23/3171; H01L 24/16; H01L 24/17; H01L 24/27; H01L 24/29; H01L 24/32; H01L 24/81; H01L 25/0657; H01L 2224/16148; H01L 2224/1712; H01L 2224/27416; H01L 2224/27614; H01L 2224/29191; H01L 2224/3201; H01L 2224/32145; H01L 2224/73204; H01L 2224/81203; H01L 2225/06513; H01L 2225/06524; H01L 2225/06527; H01L 2924/35121; H01L 2924/37001; H01L 2924/381; H01L 2924/3841

(57) ABSTRACT

Circuit packages with a polymer layer around the bump interconnects have a reduced number of shorts between the bump interconnects and have reduced underfill delamination. The circuit package includes a first component coupled to a second component through a plurality of bump interconnects employed for passing logic signals, data signals, and/or power. The bump interconnects extend from a surface of the first component and are coupled to contact pads on an opposing surface of the second component. The side surfaces of the bump interconnects extend in a direction from the second component to the first. The circuit package includes the polymer layer disposed on the surface of the first component around the bump interconnects and on the side surfaces of the bump interconnects. The polymer layer reduces shorts between the side surfaces of adjacent bump interconnects and reduces delamination of an underfill disposed between the first and second components.

### BACKGROUND

### I. Field of the Disclosure

The technology of the disclosure relates generally to semiconductor packaging and, more particularly, to flip-chip packaging with bump interconnects.

### II. Background

Electronic devices, such as cell phones, laptops, and tablets, are powered by semiconductor devices that continuously increase in performance even as their physical sizes decrease. Semiconductor devices are included in circuit packages inside electronic devices. The semiconductor devices may include various components, including analog circuits, digital processing logic circuits, and memory circuits coupled to each other in the circuit packages. These components also need to interconnect to other packages, external memories, power sources, media ports, and/or input/output devices, which involve many electric interconnects to pass clock signals, logic and control signals, data signals, and/or power supply voltage signals. Bump interconnects can be used to transfer signals between semiconductor dies that are arranged face to face adjacent to each other in a flip-chip configuration. Bump interconnects are typically arranged in arrays on a first component and interconnect with arrays of contact pads on an opposing surface of a second component. The arrays are aligned with each other such that solder tips of the bump interconnects correspond to the contact pads. The solder is heated, and the components are pressed together. As the solder cools, both a mechanical bond and an electrical connection are formed between a bump interconnect and a contact pad. As electronic devices are reduced in size, there are corresponding reductions in the sizes of circuit packages, and the bump interconnects that connect them, presenting new challenges in the package fabrication.

### SUMMARY

Aspects disclosed herein include circuit packages with bump interconnect polymer layer. Related methods of fabricating circuit packages are also disclosed. An exemplary circuit package includes a first component coupled to a second component. The components are coupled to each other through a plurality of bump interconnects employed for passing logic signals, data signals, and/or power. The bump interconnects extend from a surface of the first component and are coupled to contact pads on an opposing surface of the second component. In this regard, the side surfaces of the bump interconnects extend in a direction between the first and second components. The circuit package also includes a polymer layer disposed on the surface of the first component around the bump interconnects. In an exemplary aspect, the polymer layer is also disposed on the side surfaces of the bump interconnects. In some examples, the bump interconnects are disposed at a fine pitch, and the polymer layer reduces the occurrence of shorts between the side surfaces of adjacent bump interconnects. The polymer layer electrically insulates adjacent bump interconnects from each other. Thus, for example, in the event that solder from the solder tips comes into contact with adjacent bump interconnects, the polymer layer may prevent an electrical short between the bump interconnects. In this manner, fabrication of the circuit package may have an improved yield. In some examples, an underfill is also disposed between the first and second components, and the polymer layer can reduce delamination of the underfill from the first surface.

In this regard, in one aspect, a circuit package is disclosed. The circuit package comprises a first component comprising a plurality of contact pads on a first surface and a second component comprising a plurality of bump interconnects on a second surface. Each of the plurality of bump interconnects couples to one of the plurality of contact pads on the first surface of the first component and comprises a side surface extending in a first direction between the first component and the second component. The circuit package further comprises a polymer layer disposed on the second surface of the second component and the side surface of each of the plurality of bump interconnects, surrounding each of the plurality of bump interconnects.

In another exemplary aspect, a method of fabricating a circuit package is disclosed. The method comprises forming a first component comprising a plurality of contact pads on a first surface and forming a second component comprising a plurality of bump interconnects on a second surface, wherein each of the plurality of bump interconnects couples to one of the plurality of contact pads on the first surface and comprises a side surface extending in a first direction orthogonal to the second surface. The method further comprises forming a passivation layer disposed on the second surface around each the plurality of bump interconnects and forming a polymer layer disposed on the passivation layer around each of the plurality of bump interconnects and on the side surface of each of the plurality of bump interconnects.

In another exemplary aspect, a semiconductor die configured to be coupled in a circuit package is disclosed. The semiconductor die comprises a plurality of bump interconnects on a surface of the semiconductor die, wherein each of the plurality of bump interconnects is configured to couple to a corresponding contact pad on a surface of a circuit component of the circuit package. Each of the plurality of bump interconnects comprises a side surface extending from the semiconductor die; and a polymer layer disposed on the surface of the semiconductor die and on the side surfaces of the plurality of bump interconnects, surrounding each of the plurality of bump interconnects.

### BRIEF DESCRIPTION OF THE DRAWINGS

FIG. 1 is a cross-sectional side view of an exemplary circuit package comprising first and second components coupled with bump interconnects that are surrounded by a polymer layer;

FIGS. 2A-2C are illustrations of a circuit package in stages of fabrication according to a conventional mass-reflow process;

FIGS. 3A-3B are illustrations of a circuit package in stages of fabrication according to a first conventional thermal compression (TC) process;

FIGS. 4A-4B are illustrations of a circuit package in stages of fabrication according to a second conventional TC process;

FIG. 5 is a cross-sectional side view of a bump interconnect according to the conventional mass reflow process illustrated in FIGS. 2A-2C;

FIG. 6 is a cross-sectional side view of a bump interconnect according to the conventional thermal compression processes illustrated in FIGS. 3A-3B and 4A-4B;

FIG. 7 is a high-level flow chart illustrating a method for fabricating the exemplary circuit package in FIG. 1;

FIGS. 8A-8C are a flow chart of a method for forming a circuit component, including bump interconnects surrounded by a polymer layer for the circuit package in FIG. 1;

FIGS. 9A-9C are illustrations of cross-sections of the component and bump interconnects in stages of fabrication described in the flow chart in FIGS. 8A-8C;

FIG. 10 is a cross-sectional side view of a first example of a package component, including bump interconnects that may be employed in the circuit package of FIG. 1;

FIG. 11 is a cross-sectional side view of a second example of a package component bump interconnect that may be employed in the circuit package of FIG. 1;

FIG. 12 is a block diagram of an exemplary wireless communications device that can include the circuit package of FIG. 1; and

FIG. 13 is a block diagram of an exemplary processor-based system that can include the circuit package of FIG. 1.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed herein include circuit packages with a bump interconnect polymer layer. Related methods of fabricating circuit packages are also disclosed. An exemplary circuit package includes a first component coupled to a second component. The components are coupled to each other through a plurality of bump interconnects employed for passing logic signals, data signals, and/or power. The bump interconnects extend from a surface of the first component and are coupled to contact pads on an opposing surface of the second component. The side surfaces of the bump interconnects extend in a direction between the first and second components. The circuit package also includes a polymer layer disposed on the surface of the first component around the bump interconnects. In an exemplary aspect, the polymer layer is also disposed on the side surfaces of the bump interconnects. In some examples, the bump interconnects are disposed at a fine pitch, and the polymer layer reduces the occurrence of shorts between the side surfaces of adjacent bump interconnects. The polymer layer electrically insulates adjacent bump interconnects from each other. Thus, for example, in the event that solder from the solder tips comes into contact with adjacent bump interconnects, the polymer layer may prevent an electrical short between the bump interconnects. In this manner, fabrication of the circuit package may have an improved yield. In some examples, an underfill is also disposed between the first and second components, and the polymer layer can reduce delamination of the underfill from the first surface.

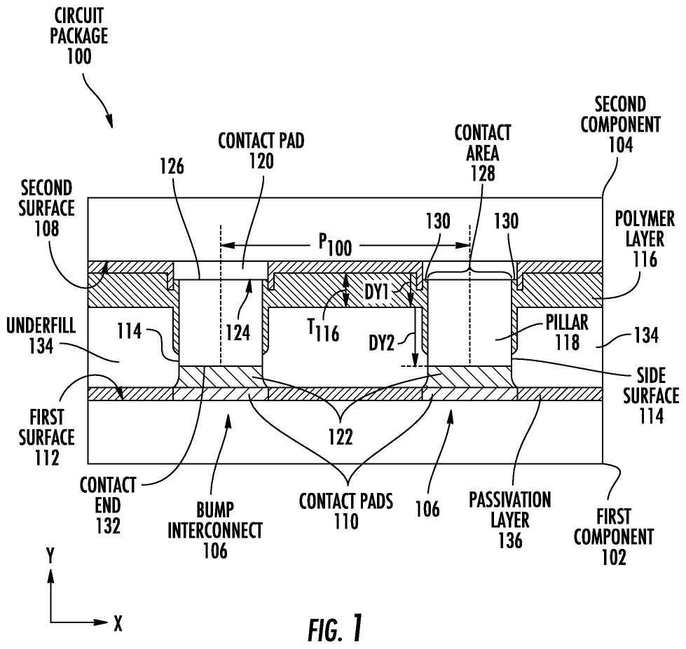

FIG. 1 is a cross-sectional side view of an exemplary circuit package 100 comprising a first component 102 and a second component 104, which are coupled to each other by bump interconnects 106. The first component 102 and the second component include circuits (not shown) electrically coupled to each other by the bump interconnects 106. The circuits on each of the first and second components 102, 104 may be passive or active circuits, where active circuits may include transistor circuits and passive circuits include passive components (e.g., resistors, capacitors, and inductors) and electrical interconnects, such as wire traces and vias. For example, the second component 104 may be a semiconductor die (e.g., chip) comprising transistor circuits, and the first component 102 may be another semiconductor die including active circuits. The first component 102 may be an interposer or package substrate for interconnecting the second component 104, to another semiconductor die (not shown) or other components in an electronic device or system. The first and second components 102, 104 may be any other type of component in a circuit package in which bump interconnects 106 are employed. Bonding components in a circuit package, such as circuit package 100, may be known as flip-chip (FC) bonding.

The bump interconnects 106 extend from a second surface 108 on the second component 104 to contact pads 110 that are on a first surface 112 of the first component 102. Side surfaces 114 of the bump interconnects 106 extend between the second component 104 and the first component 102. That is, the side surfaces extend in the Y-axis direction in FIG. 1 from the second surface 108 of the second component 104 toward the first surface 112 of the first component 102. As explained in further detail below, the circuit package 100 also includes a polymer layer 116 disposed on the second surface 108 around the bump interconnects 106 and also disposed on the side surfaces 114 of the bump interconnects 106.

Each bump interconnect 106 includes a pillar 118, a contact pad 120, and a solder tip 122. The contact pad 120 is located on the second surface 108 of the second component 104 and has a pad surface 124 to which the pillar 118 is coupled. The pillar 118 includes a base end 126 coupled to a contact area 128 of the pad surface 124. The base end 126 of the pillar 118 is in contact with the pad surface 124 in the contact area 128. The side surface 114 of the pillar 118 of the bump interconnect 106 extends from the pad surface 124. The contact area 128 may be larger than the base end 126. Therefore, the pad surface 124 also includes a second area 130 around all or at least a portion of the contact area 128. The pillar 118 also includes a contact end 132 opposite the base end 126. The bump interconnect 106 includes the solder tip 122 disposed on the contact end 132. In a fabrication process, when the second component 104 and the first component 102 are positioned together, the solder tips 122 disposed on the contact ends 132 are aligned to and may be in contact with the contact pads 110. The solder tips 122 are heated (e.g., melted, softened) to a fluid state so that the solder of the solder tips 122 adheres to the contact pads 110 on the first component 102. When the solder tips 122 are cooled and solidified, the solder tips 122 electrically couple the pillars 118 and the contact pads 110 and may also create a mechanical bond between the contact ends 132 of the pillars 118 and the contact pads 110.

As semiconductor packaging technology advances, a pitch P₁₀₀ of the bump interconnects 106 decreases, bringing the side surfaces 114 of the bump interconnects 106 closer to each other during the fabrication process. In conventional circuit packages employing bump interconnects having a fine pitch, an electrical short may be formed by a portion of a solder tip coming into contact with the side surfaces of two adjacent bump interconnects.

In an exemplary aspect disclosed herein, the circuit package 100 includes the polymer layer 116 disposed on the side surfaces 114 of the bump interconnects 106, electrically insulating the bump interconnects 106 from each other. Thus, in the event that solder from the solder tips 122 comes into contact with adjacent bump interconnects 106, the polymer layer 116 may prevent an electrical short. In this manner, fabrication of the circuit package 100 may have an improved yield.

The polymer layer 116 is also disposed on the second surface 108 of the second component 104 surrounding each of the bump interconnects 106. On the second surface 108, the polymer layer 116 is disposed to a thickness T₁₁₆, as measured in the Y-axis direction. In contrast, the polymer layer 116 disposed on the side surface 114 of each bump interconnect 106 extends farther in the Y-axis direction (e.g., in the direction from the second surface 108 toward the first surface 112) than the thickness T₁₁₆. Stated differently, the thickness T₁₁₆ of the polymer layer 116 on the second surface 108 extends a distance DY1 in the Y-axis direction. The side surfaces 114 of the bump interconnects 106 extend beyond the distance DY1 an additional distance DY2 in the Y-axis direction. The polymer layer 116 disposed on the side surface 114 of each of the plurality of bump interconnects 106 extends at least half of the additional distance DY2 in the Y-axis direction beyond the first thickness T₁₁₆ (e.g., the distance DY1).

In another aspect, the circuit package 100 includes an underfill 134 filling space between the first component 102 and the second component 104 around each bump interconnect 106. For example, the underfill 134 may be an organic material in the form of a paste or film. In some examples, the underfill 134 may be referred to as a molding compound. As explained further below, the circuit package 100 also includes a passivation layer 136 formed on the second surface 108 of the second component 104, surrounding the bump interconnects 106. In this regard, the polymer layer 116 may be disposed between the underfill 134 and the passivation layer 136. The polymer layer 116 may be an organic material, such as a polyimide, having a better bond to the underfill 134 than the underfill 134 would have with the passivation layer 136. In some examples, the underfill 134 may be an organic material, and an organic polyimide of the polymer layer 116 develops a better bond to the underfill 134 than the underfill 134 would have with the passivation layer 136 in the absence of the polymer layer 116. In this manner, the polymer layer 116 may also reduce delamination of the underfill 134 from the second component 104. As explained below, the polymer layer 116 does not need to be formed of a photosensitive polymer material and, thus, may not include a photosensitive polymer material, which reduces the cost of the polymer layer 116.

With further reference to FIG. 1, the first surface 112 may also include a passivation layer 136 and/or other layers disposed around the contact pads 110 to protect the first surface 112 and provide better adhesion to the underfill 134.

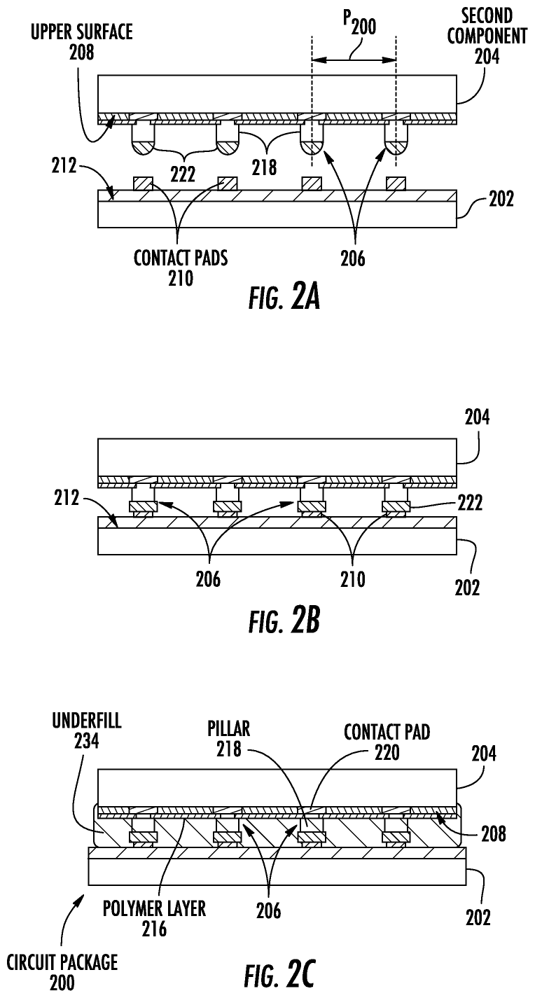

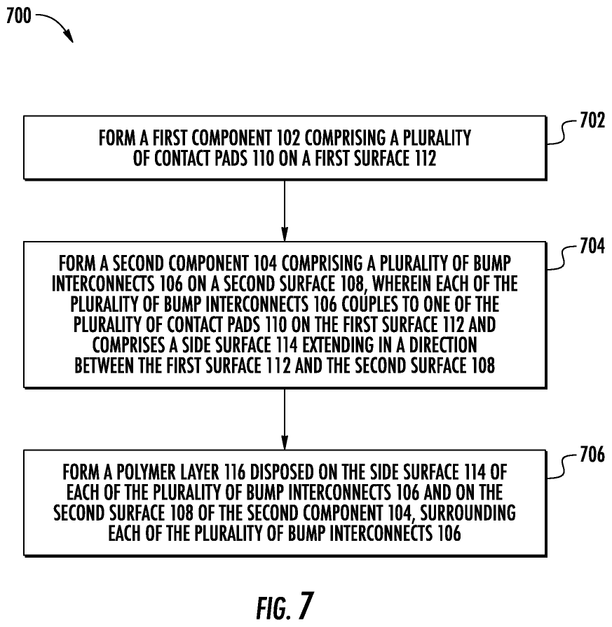

FIGS. 2A-2C, 3A-3B, and 4A-4B are illustrations of conventional processes for fabricating circuit packages, and FIGS. 5 and 6 are illustrations of bump interconnects fabricated according to such processes. FIGS. 2A-6 are provided to show conventional aspects contrasting to the exemplary circuit package 100 in FIG. 1 and exemplary method 700 in FIGS. 7A-7C.

FIGS. 2A-2C illustrate a circuit package 200 in stages of fabrication according to a conventional mass-reflow process. In FIG. 2A, a first component 202 and a second component 204 are shown. The second component 204 includes bump interconnects 206 on an upper surface 208. The first component 202 includes contact pads 210 on a lower surface 212. The contact pads 210 on the lower surface 212 are arranged in an array pattern corresponding to an array pattern of the bump interconnects 206 on the upper surface 208. The patterns of the bump interconnects 206 may be disposed at a center to center pitch P₂₀₀ of equal to or greater than 60 microns (μm), such as 80 μm, with the bump interconnects 206 having diameters of equal to or greater than 35 μm. The bump interconnects include pillars 218 and solder tips 222. Further detail of the bump interconnects 206 will be provided with reference to FIG. 5.

In FIG. 2B, the first and second components 202, 204 are placed (e.g., on a conveyor) in an oven or heater and heated to a sufficient temperature to cause the solder tips 222 to become fluid and adhere to the contact pads 210 on the lower surface 212. Upon cooling, the solder tips 222 return to a solid state and form a mechanical bond that electrically couples the bump interconnects 206 to the corresponding contact pads 210.

In FIG. 2C, an underfill 234 has been injected or otherwise provided to fill spaces between the first component 202 and the second component 204 and around the bump interconnects 206. It is noted that a polymer layer 216 (e.g., organic polymer) is formed on the upper surface 208 to provide a strong bond to the underfill 234. The bump interconnects 206 include pillars 218 coupled to contact pads 220. The polymer layer 216 is also provided to reduce stresses caused by expansion and contraction of the pillars 218 and the contact pads 220 at different rates during the heating and cooling stages of the process in FIGS. 2A-2C, as discussed further with reference to FIG. 5.

As noted above, technology improvements have reduced the sizes of semiconductor dies, interposers, substrates, etc., but the number of input and output connections to such components may remain the same or even increase. Thus, arrays of bump interconnects have been developed having a finer pitch (e.g., in the range of 20 μm to 30 μm, and, more specifically, 25 μm) and diameters in the range of 10 μm to 20 μm (e.g., 13 μm).

FIGS. 3A-3B are illustrations of a circuit package 300 in stages of fabrication according to a first conventional thermal compression process. Thermal compression processes are employed for circuit packages 300 employing fine pitch bump interconnects 306. Due in part to the smaller pitches of the bump interconnects 306, the difficulties associated with fabricating using the mass reflow process increase. In the thermal compression (TC) process shown in FIGS. 3A-3B, circuit packages 300 are fabricated in smaller batches using an apparatus 340. As shown in FIG. 3A, the apparatus 340 picks up and holds a second component 304 and heats the second component 304 to soften (e.g., to a fluid state) solder tips 322. The second component 304 is pressed onto the first component 302, compressing solder tips 322 to the contact pads 310 on the second component 304. As the second component 304 cools, the bump interconnects 306 bond to contact pads 310 on a surface 312. The apparatus 340 is configured to heat the second component 304 without heating the first component 302. Consequently, the first component 302 does not experience a heating and cooling (e.g., expansion and contraction) cycle, which helps to reduce stress between the bump interconnects 306 and the contact pads 310 on the first surface 308. FIG. 3B illustrates the circuit package 300 after an underfill 334 has been added (e.g., by injection or other means) in the spaces between the first component 302 and the second component 304.

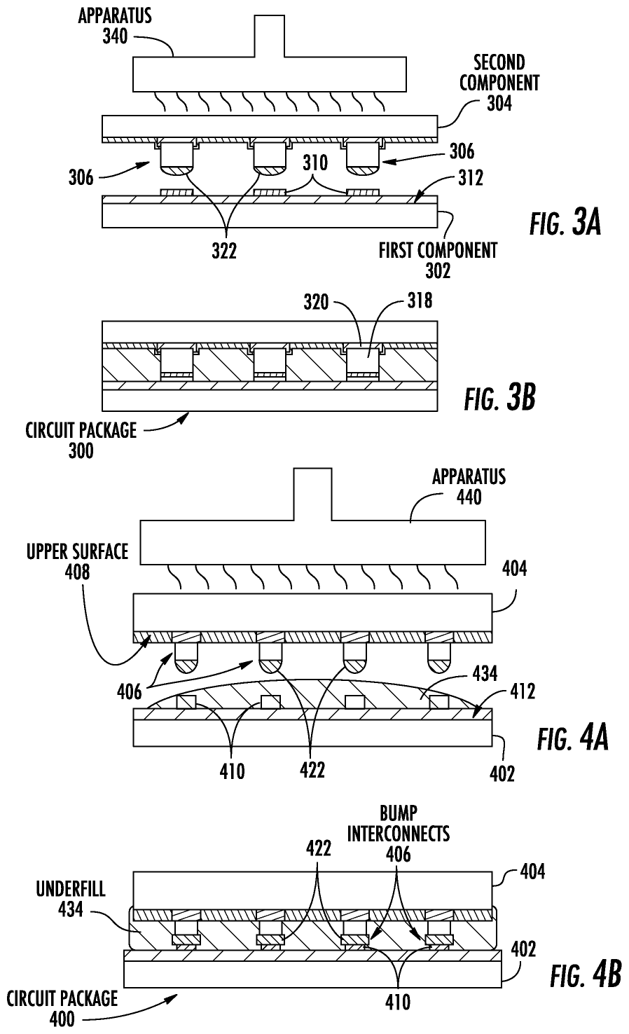

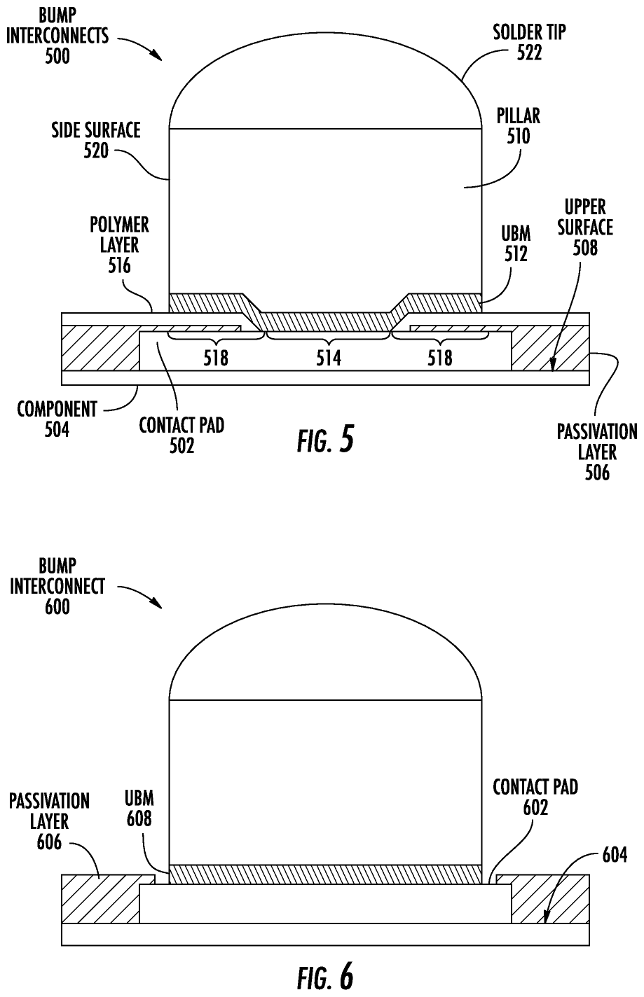

FIGS. 4A-4B illustrate stages of fabrication of a circuit package 400 according to a second conventional thermal compression process. Here, an apparatus 440 heats a second component 404 having bump interconnects 406 on an upper surface 408, as in FIG. 3A. The apparatus 440 heats the second component 404 to melt solder tips 422. However, rather than adding an underfill 434 after the second component 404 is pressed together with the first component 402 (as in FIGS. 3A-3B), the underfill 434 is added or disposed onto a surface 412 of the first component 402 at the stage shown in FIG. 4A. FIG. 4B shows the second component 404 pressed together with the first component 402 to couple solder tips 422 to the contact pads 410 on the first component 402. The bump interconnects 406 may be pushed through the underfill 434, and air/gas may be forced out in this process, leaving the underfill 434 filling the spaces between the first and second components 402, 404. As in the example in FIGS. 3A-3B, the first component 402 does not experience a heating and cooling cycle, which reduces stresses in the bump interconnects 406 in the completed circuit package 400.

Because the first components 302 and 402 do not experience the heating and cooling cycles, which reduces stresses in the circuit packages 300 and 400, the need for a polymer layer, such as the polymer layer 216 in FIGS. 2A-2C, is reduced. In addition, the polymer layer 216 in FIGS. 2A-2C is formed by adding a layer of a photosensitive polymer material to the second component 204 and patterning the polymer material using photolithographic methods to form openings for the bump interconnects 406. However, as bump interconnect pitches are reduced and bump interconnect diameters are reduced, a size of an opening in the polymer layer 216 would also be reduced, and photolithographic methods are not capable of producing sufficiently small openings in the polymer materials used for the polymer layer 216.

Since the need for stress reduction provided by the polymer layer 216 decreases with finer pitch bump interconnects, and it has become more challenging to fabricate a polymer layer as bump interconnect pitches are reduced, polymer layers have been omitted from circuit packages 300 and 400 fabricated according to the thermal compression methods in FIGS. 3A-3B and 4A-4B.

FIG. 5 is a cross-sectional side view of a bump interconnect 500, which is an example formed according to the conventional mass reflow process illustrated in FIGS. 2A-2C. That is, the bump interconnect 500 is not a fine-pitched bump interconnect, so it may be formed by the mass-reflow method discussed above. The bump interconnect 500 includes a contact pad 502 formed on a component 504. The contact pad 502 is formed of a conductive material, such as a metal. A protective passivation layer 506 is disposed on an upper surface 508 of the component 504 around the contact pad 502. The bump interconnect 500 includes a pillar 510 and an under-bump metal (UBM) 512 between the pillar 510 and the contact pad 502. The UBM 512 may provide a better bond to the contact pad 502 than a material of the pillar 510, which is selected for lower resistance, for example.

As noted above, the bump interconnect 500 is larger (e.g., in area) than a fine-pitched bump interconnect, and the stresses associated with the heating and cooling cycles increase with the area of the bump interconnect 500. To reduce such stresses, contact between the UBM 512 and the contact pad 502 is limited to an area 514, having a smaller diameter than the pillar 510. Limiting the area of contact includes forming the passivation layer 506 and a polymer layer 516 on an outer area 518 of the contact pad 502 before the UBM 512 is formed on the area 514. In detail, the passivation layer 506 and the polymer layer 516 are individually disposed on the contact pad 502 and patterned to form openings corresponding to the area 514. The UBM 512 is formed on the area 514 to couple to the contact pad 502. The UBM also extends out onto the outer area 518 (e.g., on the polymer layer 516 and the passivation layer 506). In the outer area 518, the UBM 512 does not have a contact to the contact pad 502, which reduces lateral stresses that may be caused between the UBM 512 and the contact pad 502 during the heating and cooling cycle. It is noted that the polymer layer 516 is under the pillar 510 (e.g., between the pillar 510 and the contact pad 502) but not on a side surface 520 of the bump interconnect 500. The bump interconnect 500 also includes a solder tip 522.

In contrast to the larger pitch bump interconnect 500 shown in FIG. 5, FIG. 6 is a cross-sectional side view of a fine pitch bump interconnect 600 according to the conventional thermal compression processes illustrated in FIGS. 3A-3B or 4A-4B. In addition to having a smaller center-to-center distance between adjacent bump interconnects in an array of bump interconnects, the bump interconnect 600 is also smaller in diameter than the bump interconnect 500. The bump interconnect 600 includes a contact pad 602 (e.g., a metal pad) disposed on a surface 604 and a passivation layer 606 disposed on the surface 604 around the contact pad 602. As noted above, typical photolithographic processing methods are not able to pattern a polymer (e.g., a polyimide) with openings that are small enough to create a limited contact area (e.g., corresponding to the area 514 in FIG. 5) for a fine pitch bump interconnect. This prevents, for use with fine pitched bump interconnects, the use of polymer in the manner in which it is used for larger-sized bump interconnects. Fortunately, because the area of bump interconnect 600 is smaller, there is less area of contact with the surface 604, so the amount of stress created during the heating and cooling cycles is less than with larger bump interconnects. Therefore, there is less need to reduce the area of contact between a UBM 608 and the contact pad 602, and the lack of a polymer layer to reduce contact area is not problematic with respect to heat stresses. It is noted that the passivation layer 606 disposed on the surface 604 around the contact 602 may also be disposed on a portion of the contact pad 602, but not between the UBM 608 and the contact pad 602.

However, the absence of a polymer layer causes the underfill material to be disposed directly on the passivation layer 606. The passivation layer 606 is an inorganic material that does not adhere well to an organic underfill. As a result, the weaker organic/inorganic bond can increase the incidence of delamination of the underfill, causing electronic devices containing circuit packages with bump interconnects 600 to be less reliable.

FIG. 7 is a high-level flow chart illustrating an exemplary method 700 for fabricating the circuit package 100 in FIG. 1. The method includes forming a first component 102 comprising a plurality of contact pads 110 on a first surface 112 (block 702). The method includes forming a second component 104 comprising a plurality of bump interconnects 106 on a second surface 108, wherein each of the plurality of bump interconnects 106 couples to one of the plurality of contact pads 110 on the first surface 112 and comprises a side surface 114 extending in a direction (Y-axis) between the second surface 108 and the first surface 112 (block 704). The method further includes forming a polymer layer 116 disposed on the side surface 114 of each of the plurality of bump interconnects 106, and on the second surface 108 of the second component 104, surrounding each of the plurality of bump interconnects 106 (block 706).

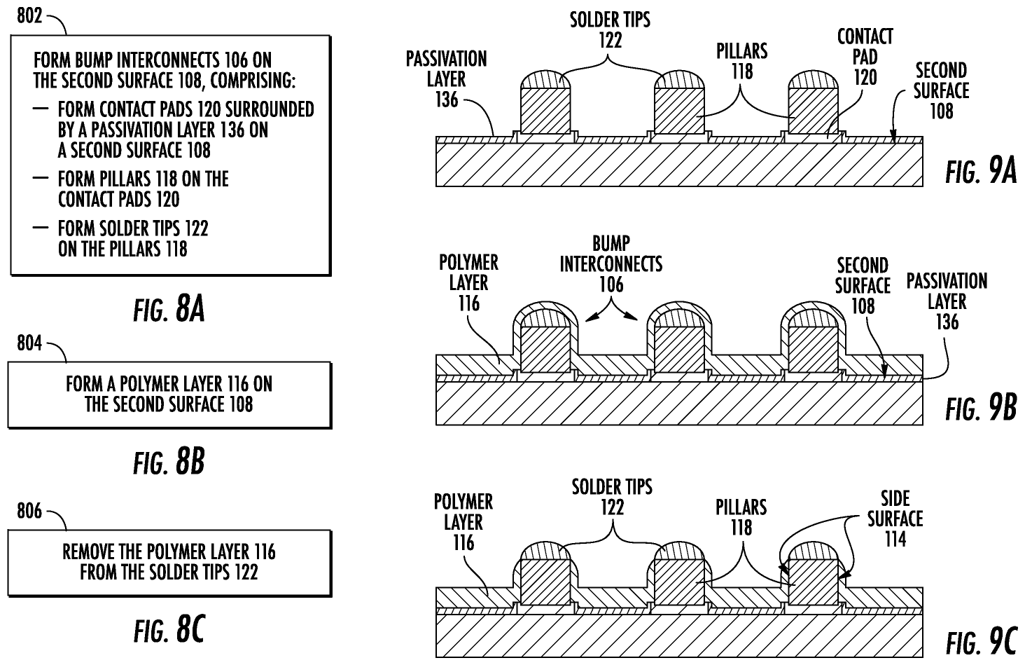

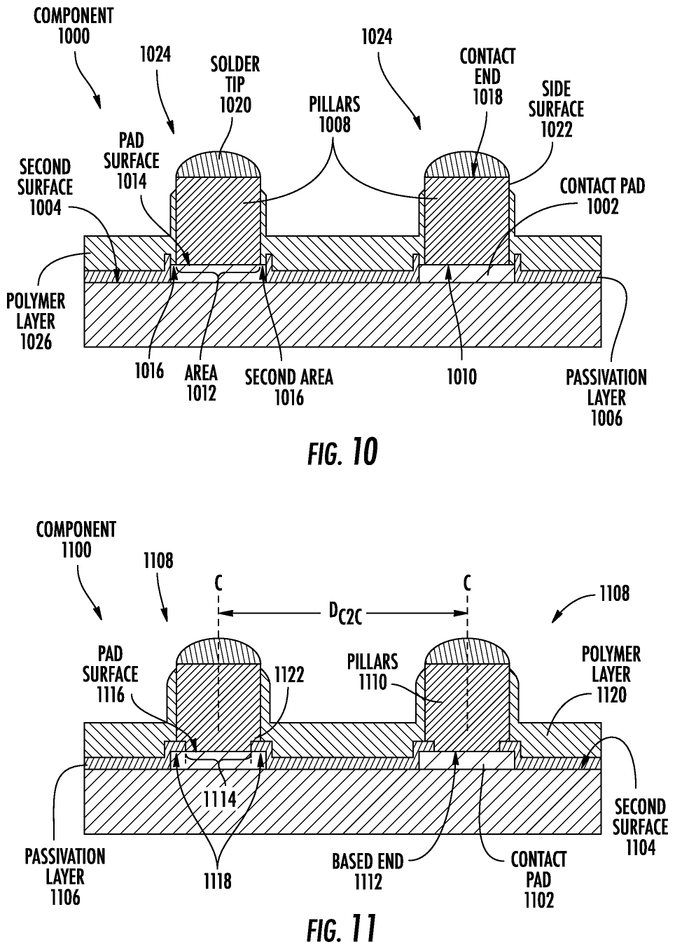

FIGS. 8A-8C are a flow chart detailing exemplary aspects of a method 800 for forming the second component 104 for the circuit package 100 in FIG. 1, including bump interconnects 106 surrounded by polymer layer 116. FIGS. 9A-9C are illustrations of cross-sections of the second component 104 at fabrication stages 900A-900C described in method blocks 802, 804, and 806, respectively. Features that are the same in FIGS. 9A-9C as in FIG. 1 will be numbered the same.

FIG. 8A describes forming bump interconnects 106 on the second surface 108, comprising: forming contact pads 120 surrounded by a passivation layer 136 on a second surface 108, forming pillars 118 on the contact pads 120, and forming solder tips 122 on the pillars 118 (block 802), as shown in FIG. 9A. These steps of the method 800 may be performed according to the conventional processes.

FIG. 8B describes forming a polymer layer 116 on the second surface 108 (block 804), which may further include spin-coating the polymer layer 116 onto the passivation layer 136 and onto the bump interconnects 106, as shown in FIG. 9B. Spin-coating is merely one example of forming the polymer material onto the second surface 108. As discussed above, the polymer layer 116 may be a polyimide. In particular, the polymer layer 116 may be an organic polyimide that will bond well with an organic underfill to reduce delamination.

FIG. 8C describes removing the polymer layer 116 from the solder tips 122 (block 806), as shown in FIG. 9C. Removing the polymer layer 116 from the solder tips 122 may include, but is not limited to, plasma etching or dry etching the polymer layer 116 with oxygen or nitrogen gas. Though the polymer layer 116 is removed from the solder tips 122, the polymer layer 116 may be partially removed from less than half of the side surfaces 114 of the pillars 118. The polymer layer 116 will remain on at least 50% of the side surfaces 114 that extend beyond the polymer layer 116 on the second surface 108.

Following block 806, processing may resume according to the conventional steps for thermal compression TC bonding, as shown in FIGS. 3A-3B or 4A-4B.

FIG. 10 is a cross-sectional side view of a component 1000 corresponding to the second component 104 in FIG. 1. The component 1000 may be a semiconductor die, an interposer, or some other package component, such as a module substrate. The component 1000 has contact pads 1002 that are formed on a surface 1004 to provide points at which external circuits may electrically couple to internal circuits (not shown) of the component 1000. The surface 1004 is protected by a passivation layer 1006 formed on the surface 1004 in areas surrounding the contact pads 1002.

The component 1000 also includes pillars 1008 on the contact pads 1002. Specifically, a base end 1010 of the pillars 1008 is coupled to an area 1012 of a pad surface 1014 of the contact pads 1002. The area 1012 does not cover the entire pad surface 1014 of the contact pad 1002. Thus, the pad surface 1014 also includes a second area 1016 around the base end 1010 of the pillar 1008. The pillars 1008 also have a contact end 1018 opposite the base end 1010. A solder tip 1020 is disposed on the contact end 1018. In addition, the pillars 1008 include a side surface 1022 that extends from the surface 1004. The side surface 1022 extends in a direction from the surface 1004 and toward another component in the circuit package 100. In some examples, the side surface 1022 extends in a direction orthogonal to the surface 1004.

Bump interconnects 1024 include the contact pads 1002, the pillars 1008, and the solder tips 1020. A polymer layer 1026 is formed, according to the process described with reference to FIGS. 8B and 9B, on the surface 1004 to a thickness T₁₁₆ and also on the side surfaces 1022. On the surface 1004, the polymer layer 1026 surrounds the bump interconnects 1024.

In the component 1000 in FIG. 10, the passivation layer 1006 does not extend onto the second area 1016 of the pad surface 1014. Thus, when the polymer layer 1026 is added, the polymer layer 1026 is disposed directly on the second area 1016 of the pad surface 1014 of the contact pad 1002 around the base end 1010 of the pillar 1008.

FIG. 11 is a cross-sectional side view of another component 1100, corresponding to the second component 104, in FIG. 1. The component 1100 in FIG. 11 is the same as the component 1000 in FIG. 10 except as described here. The component 1100 includes contact pads 1102 on a surface 1104, and a passivation layer 1106 disposed on the surface 1104 around the contact pads 1102. The component 1100 includes bump interconnects 1108, including pillars 1110. Each of the pillars 1110 has a base end 1112 that couples to a first area 1114 of a pad surface 1116 of the contact pads 1102. Each of the pad surfaces 1116 includes a second area 1118 around the first areas 1114, which is under the base end 1112 of the pillar 1110.

As shown, the passivation layer 1106 is disposed on the second area 1118. In this manner, the passivation layer 1106 is disposed between a polymer layer 1120 and the second area 1118 of the pad surface 1116 of the contact pad 1102 around the pillar 1110. In some examples, the passivation layer 1106 is disposed directly between the polymer layer 1120 and the second area 1118 of the pad surface 1116 of the contact pad 1102 and directly between a portion 1122 of the pillar 1110 and the second area 1118 of the pad surface 1116 of the contact pad 1102.

The passivation layer 1106 may be extended onto the second area 1118 of the contact pad 1102 to reduce the first area 1114 to reduce stresses caused by the heating and cooling cycle.

The bump interconnects 1108 in FIG. 11 each have a center axis C extending in the longitudinal direction of the bump interconnect 1108, which is in the Y-axis direction in FIG. 11. A distance D_{C2C} is a center-to-center pitch distance from the center axis C of a first bump interconnect 1108 to a center axis C of a nearest adjacent bump interconnect 1108. In some examples of a fine pitch bump interconnect, the center-to-center pitch distance D_{C2C} is in a range between 5 microns (μm) and 40 μm. In some examples, the center-to-center pitch distance D_{C2C} is in a range between 5 μm and 25 μm.

The bump interconnects 1108 in FIG. 11, as well as the bump interconnects 106 in FIG. 1, and the bump interconnects 1024 in FIG. 10, which may be controller collapse chip connect (C4) bumps, which may be arranged in a two-dimensional array on the components 104, 1000 and 1100 in FIGS. 1, 10, and 11.

According to aspects disclosed herein, the circuit package comprising a polymer layer on the side surfaces of the bump interconnects to reduce shorts and delamination may be provided in or integrated into any processor-based device. Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

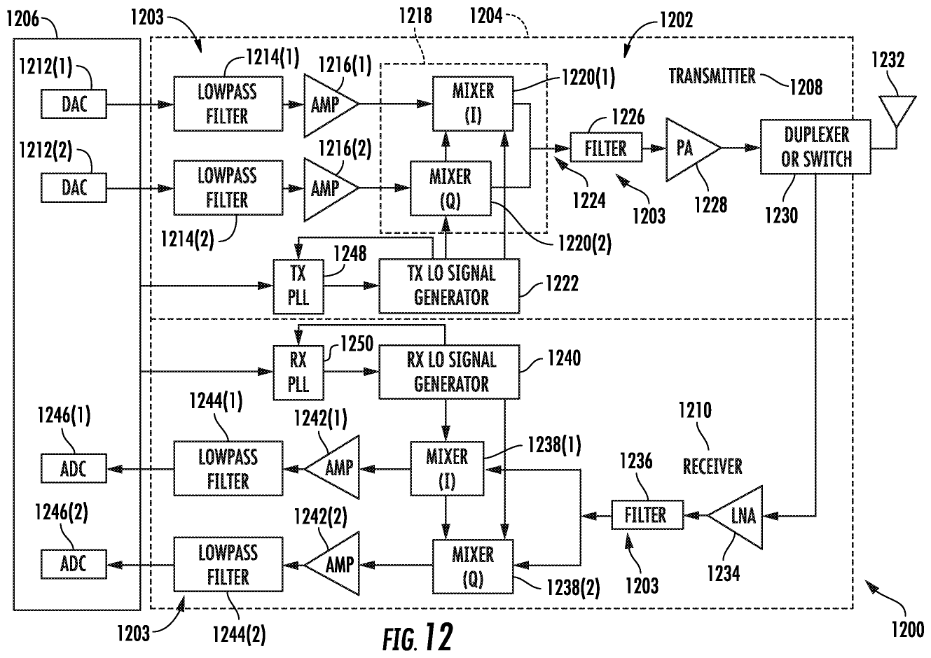

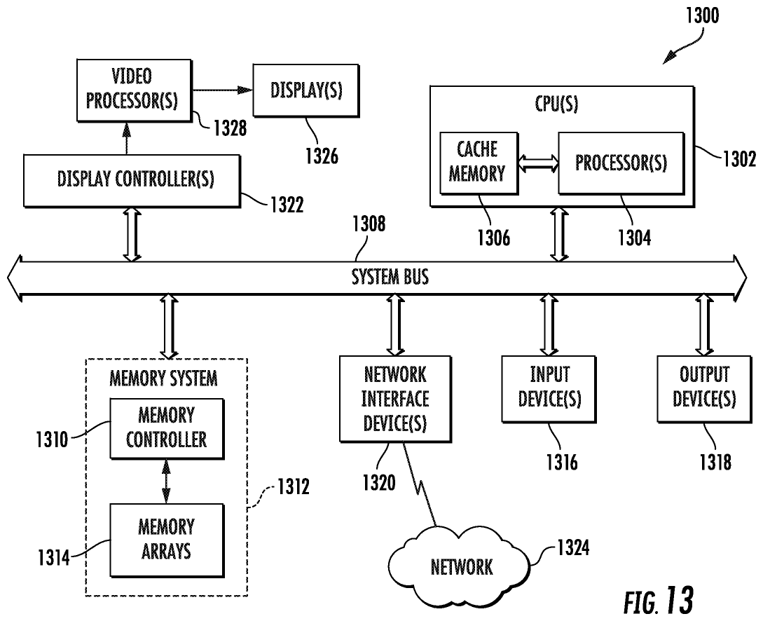

FIG. 12 illustrates an exemplary wireless communications device 1200 that includes radio-frequency (RF) components formed from one or more integrated circuits (ICs) 1202 and can include an exemplary circuit package including a polymer layer disposed on side surfaces of bump interconnects between components, as illustrated in FIGS. 1, 10, and 11, and according to any of the aspects disclosed herein. The wireless communications device 1200 may include or be provided in any of the above-referenced devices as examples. As shown in FIG. 12, the wireless communications device 1200 includes a transceiver 1204 and a data processor 1206. The data processor 1206 may include a memory to store data and program codes. The transceiver 1204 includes a transmitter 1208 and a receiver 1210 that support bi-directional communications. In general, the wireless communications device 1200 may include any number of transmitters 1208 and/or receivers 1210 for any number of communication systems and frequency bands. All or a portion of the transceiver 1204 may be implemented on one or more analog ICs, RFICs, mixed-signal ICs, etc.

The transmitter 1208 or the receiver 1210 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage and then from IF to baseband in another stage. In the direct-conversion architecture, a signal is frequency-converted between RF and baseband in one stage. The super-heterodyne and direct-conversion architectures may use different circuit blocks and/or have different requirements. In the wireless communications device 1200 in FIG. 12, the transmitter 1208 and the receiver 1210 are implemented with the direct-conversion architecture.

In the transmit path, the data processor 1206 processes data to be transmitted and provides I and Q analog output signals to the transmitter 1208. In the exemplary wireless communications device 1200, the data processor 1206 includes digital-to-analog converters (DACs) 1212(1), 1212(2) for converting digital signals generated by the data processor 1206 into the I and Q analog output signals, e.g., I and Q output currents, for further processing.

Within the transmitter 1208, lowpass filters 1214(1), 1214(2) filter the I and Q analog output signals, respectively, to remove undesired signals caused by the prior digital-to-analog conversion. Amplifiers (AMPs) 1216(1), 1216(2) amplify the signals from the lowpass filters 1214(1), 1214(2), respectively, and provide I and Q baseband signals. An upconverter 1218 upconverts the I and Q baseband signals with I and Q transmit (TX) local oscillator (LO) signals from a TX LO signal generator 1222 through mixers 1220(1), 1220(2) to provide an upconverted signal 1224. A filter 1226 filters the upconverted signal 1224 to remove undesired signals caused by the frequency upconversion as well as noise in a receive frequency band. A power amplifier (PA) 1228 amplifies the upconverted signal 1224 from the filter 1226 to obtain the desired output power level and provides a transmit RF signal. The transmit RF signal is routed through a duplexer or switch 1230 and transmitted via an antenna 1232. Any of the lowpass filters 1214(1) and 1214(2), or the filter 1226, may be an acoustic wave filter (AW filter) packages 1203.

In the receive path, the antenna 1232 receives signals transmitted by base stations and provides a received RF signal, which is routed through the duplexer or switch 1230 and provided to a low noise amplifier (LNA) 1234. The duplexer or switch 1230 is designed to operate with a specific receive (RX)-to-TX duplexer frequency separation, such that RX signals are isolated from TX signals. The received RF signal is amplified by the LNA 1234 and filtered by a filter 1236 to obtain a desired RF input signal. Downconversion mixers 1238(1), 1238(2) mix the output of the filter 1236 with I and Q RX LO signals (i.e., LO_I and LO_Q) from an RX LO signal generator 1240 to generate I and Q baseband signals. The I and Q baseband signals are amplified by AMPs 1242(1), 1242(2) and further filtered by lowpass filters 1244(1), 1244(2) to obtain I and Q analog input signals, which are provided to the data processor 1206. In this example, the data processor 1206 includes analog-to-digital converters (ADCs) 1246(1), 1246(2) for converting the analog input signals into digital signals to be further processed by the data processor 1206.

In the wireless communications device 1200 of FIG. 12, the TX LO signal generator 1222 generates the I and Q TX LO signals used for frequency upconversion, while the RX LO signal generator 1240 generates the I and Q RX LO signals used for frequency downconversion. Each LO signal is a periodic signal with a particular fundamental frequency. A TX phase-locked loop (PLL) circuit 1248 receives timing information from the data processor 1206 and generates a control signal used to adjust the frequency and/or phase of the TX LO signals from the TX LO signal generator 1222. Similarly, an RX PLL circuit 1250 receives timing information from the data processor 1206 and generates a control signal used to adjust the frequency and/or phase of the RX LO signals from the RX LO signal generator 1240.

Wireless communications devices 1200 that can each include an exemplary circuit package including a polymer layer disposed on side surfaces of bump interconnects between components, as illustrated in FIGS. 1, 10, and 11, and according to any of the aspects disclosed herein, may be provided in or integrated into any processor-based device. Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

FIG. 13 illustrates an example of a processor-based system 1300, including circuits including an exemplary circuit package including a polymer layer disposed on side surfaces of bump interconnects between components, as illustrated in FIGS. 1, 10, and 11, and according to any aspects disclosed herein. In this example, the processor-based system 1300 includes one or more central processor units (CPUs) 1302, which may also be referred to as CPU or processor cores, each including one or more processors 1304. The CPU(s) 1302 may have cache memory 1306 coupled to the processor(s) 1304 for rapid access to temporarily stored data. The CPU(s) 1302 is coupled to a system bus 1308 and can intercouple master and slave devices included in the processor-based system 1300. As is well known, the CPU(s) 1302 communicates with these other devices by exchanging address, control, and data information over the system bus 1308. For example, the CPU(s) 1302 can communicate bus transaction requests to a memory controller 1310 as an example of a slave device. Although not illustrated in FIG. 13, multiple system buses 1308 could be provided; wherein each system bus 1308 constitutes a different fabric.

Other master and slave devices can be connected to the system bus 1308. As illustrated in FIG. 13, these devices can include a memory system 1312 that includes the memory controller 1310 and one or more memory arrays 1314, one or more input devices 1316, one or more output devices 1318, one or more network interface devices 1320, and one or more display controllers 1322, as examples. The input device(s) 1316 can include any type of input device, including, but not limited to, input keys, switches, voice processors, etc. The output device(s) 1318 can include any type of output device, including, but not limited to, audio, video, other visual indicators, etc. The network interface device(s) 1320 can be any device configured to allow an exchange of data to and from a network 1324. The network 1324 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 1320 can be configured to support any type of communications protocol desired.

The CPU(s) 1302 may also be configured to access the display controller(s) 1322 over the system bus 1308 to control information sent to one or more displays 1326. The display controller(s) 1322 sends information to the display(s) 1326 to be displayed via one or more video processors 1328, which process the information to be displayed into a format suitable for the display(s) 1326. The display(s) 1326 can include any type of display, including, but not limited to, a cathode ray tube (CRT), a liquid crystal display (LCD), a plasma display, or a light-emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or another computer-readable medium and executed by a processor or other processing device, or combinations of both. As examples, the master and slave devices described herein may be employed in any circuit, hardware component, IC, or IC chip. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware and may reside, for example, in Random Access Memory (RAM), flash memory, Read-Only Memory (ROM), Electrically Programmable ROM (EPROM), Electrically Erasable Programmable ROM (EEPROM), registers, a hard disk, a removable disk, a CD-ROM, or any other form of computer-readable medium known in the art. An exemplary storage medium is coupled to the processor such that the processor can read information from and write information to the storage medium. In the alternative, the storage medium may be integral to the processor. The processor and the storage medium may reside in an ASIC. The ASIC may reside in a remote station. Alternatively, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in several different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using various technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

Implementation examples are described in the following numbered clauses:
1. A circuit package, comprising:
   a first component comprising a plurality of contact pads on a first surface;
   a second component comprising a plurality of bump interconnects on a second surface, wherein each of the plurality of bump interconnects is coupled to one of the plurality of contact pads on the first surface of the first component and comprises a side surface extending in a first direction between the first surface and the second surface; and
   a polymer layer disposed on the side surface of each of the plurality of bump interconnects and on the second surface of the second component, surrounding each of the plurality of bump interconnects.
2. The circuit package of clause 1, wherein:
   the polymer layer disposed on the second surface comprises a first thickness in the first direction; and
   the polymer layer disposed on the side surface of each of the plurality of bump interconnects extends farther in the first direction than the first thickness.
3. The circuit package of clause 2, wherein:
   the side surface of each of the plurality of bump interconnects extends in the first direction a first distance beyond the first thickness of the polymer layer; and
   the polymer layer disposed on the side surface extends in the first direction at least half of the first distance.
4. The circuit package of any one of clause 1 to clause 3, wherein the polymer layer comprises a polyimide.
5. The circuit package of clause 4, wherein the polyimide does not comprise a photosensitive polymer.
6. The circuit package of any one of clause 1 to clause 5, further comprising an organic underfill on the polymer layer between the first component and the second component around each of the plurality of bump interconnects.
7. The circuit package of any one of clause 1 to clause 6, further comprising a passivation layer disposed between the polymer layer and the second surface of the second component around each the plurality of bump interconnects.
8. The circuit package of any one of clause 1 to clause 7, each of the plurality of bump interconnects further comprising:
   a contact pad disposed on the second surface, the contact pad comprising a pad surface having a first area; and
   a pillar comprising:
      a base surface coupled to the pad surface in the first area; and
      the side surface extending from the pad surface.
9. The circuit package of clause 8, wherein, in each of the plurality of bump interconnects, the polymer layer is disposed directly on a second area of the pad surface of the contact pad around the pillar.
10. The circuit package of clause 8 or clause 9, wherein, in each of the plurality of bump interconnects, the passivation layer is disposed between the polymer layer and a second area of the pad surface of the contact pad around the pillar.
11. The circuit package of any one of clause 8 to clause 10, wherein the passivation layer is disposed directly between the polymer layer and the second area of the pad surface of the contact pad and directly between, in the first direction, a portion of the pillar and the second area of the pad surface of the contact pad.
12. The circuit package of any one of clause 8 to clause 11, each of the plurality of bump interconnects further comprising:
   a contact end of the pillar; and
   solder tip disposed on the contact end,
   wherein each of the plurality of bump interconnects coupled to one of the plurality of contact pads on the first surface of the first component further comprises the solder tip disposed between the contact end of the pillar and the contact pad.
13. The circuit package of any one of clause 1 to clause 12, wherein:
   each of the plurality of bump interconnects comprises a center axis extending in a longitudinal direction of the bump interconnect; and
   a center-to-center pitch distance from a center axis of a first bump interconnect to a center axis of a nearest adjacent bump interconnect of the plurality of bump interconnects is between 20 and 30 microns.
14. The circuit package of clause 13, wherein the center-to-center pitch distance is 25 microns.
15. The circuit package of any one of clause 1 to clause 14, wherein:
   a first one of the first component and the second component comprises a semiconductor die; and
   the second one of the first component and the second component comprises one of a semiconductor die, an interposer, and a package substrate.
16. The circuit package of any one of clause 1 to clause 15, wherein the plurality of bump interconnects comprise controller collapse chip connect (C4) bumps.
17. The circuit package of any one of clause 1 to clause 16, wherein the plurality of bump interconnects comprise a two-dimensional array of bump interconnects.
18. The circuit package of any one of clause 1 to clause 17 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multi copter.
19. A method of fabricating a circuit package, comprising:
   forming a first component comprising a plurality of contact pads on a first surface;
   forming a second component comprising a plurality of bump interconnects on a second surface, wherein each of the plurality of bump interconnects couples to one of the plurality of contact pads on the first surface and comprises a side surface extending in a first direction between the first surface and the second surface; and
   forming a polymer layer disposed on the side surface of each of the plurality of bump interconnects and on the second surface of the second component, surrounding each of the plurality of bump interconnects.
20. The method of clause 19, further comprising:
   employing thermal compression bonding to couple the plurality of bump interconnects on the second component to the plurality of contact pads on the first component.
21. The method of clause 19 or clause 20, wherein forming the polymer layer further comprises:
   spin-coating the polymer layer onto the second surface of the second component and a side surface and an end surface of each of the plurality of bump interconnects; and
   etching the polymer layer from the end surface of each of the plurality of bump interconnects.
22. A semiconductor die configured to be coupled in a circuit package, the semiconductor die comprising:
   a plurality of bump interconnects on a surface of the semiconductor die, wherein:
      each of the plurality of bump interconnects is configured to couple to a corresponding contact pad on a surface of a circuit component of the circuit package; and
      each of the plurality of bump interconnects comprises a side surface extending from the semiconductor die; and
   a polymer layer disposed on the surface of the semiconductor die and on the side surface of each of the plurality of bump interconnects, surrounding each of the plurality of bump interconnects.

What is claimed is:

1. A circuit package, comprising:
a first component comprising a plurality of contact pads on a first surface;
a second component comprising a plurality of bump interconnects on a second surface, wherein each of the plurality of bump interconnects is coupled to one of the plurality of contact pads on the first surface of the first component and comprises a side surface extending in a first direction between the first surface and the second surface; and
a polymer layer disposed on the side surface of each of the plurality of bump interconnects and on the second surface of the second component, surrounding each of the plurality of bump interconnects.

2. The circuit package of claim 1, wherein:
the polymer layer disposed on the second surface comprises a first thickness in the first direction; and
the polymer layer disposed on the side surface of each of the plurality of bump interconnects extends farther in the first direction than the first thickness.

3. The circuit package of claim 2, wherein:
the side surface of each of the plurality of bump interconnects extends in the first direction a first distance beyond the first thickness of the polymer layer; and
the polymer layer disposed on the side surface extends in the first direction at least half of the first distance.

4. The circuit package of claim 1, wherein the polymer layer comprises a polyimide.

5. The circuit package of claim 4, wherein the polyimide does not comprise a photosensitive polymer.

6. The circuit package of claim 5, further comprising an organic underfill on the polymer layer between the first component and the second component around each of the plurality of bump interconnects.

7. The circuit package of claim 1, further comprising a passivation layer disposed between the polymer layer and the second surface of the second component around each the plurality of bump interconnects.

8. The circuit package of claim 1, each of the plurality of bump interconnects further comprising:
a contact pad disposed on the second surface, the contact pad comprising a pad surface having a first area; and
a pillar comprising:
a base surface coupled to the pad surface in the first area; and
the side surface extending from the pad surface.

9. The circuit package of claim 8, wherein, in each of the plurality of bump interconnects, the polymer layer is disposed directly on a second area of the pad surface of the contact pad around the pillar.

10. The circuit package of claim 8, wherein, in each of the plurality of bump interconnects, the passivation layer is disposed between the polymer layer and a second area of the pad surface of the contact pad around the pillar.

11. The circuit package of claim 10, wherein the passivation layer is disposed directly between the polymer layer and the second area of the pad surface of the contact pad and directly between, in the first direction, a portion of the pillar and the second area of the pad surface of the contact pad.

12. The circuit package of claim 8, each of the plurality of bump interconnects further comprising:
a contact end of the pillar; and
solder tip disposed on the contact end,
wherein each of the plurality of bump interconnects coupled to one of the plurality of contact pads on the first surface of the first component further comprises the solder tip disposed between the contact end of the pillar and the contact pad.

13. The circuit package of claim 1, wherein:
each of the plurality of bump interconnects comprises a center axis extending in a longitudinal direction of the bump interconnect; and
a center-to-center pitch distance from a center axis of a first bump interconnect to a center axis of a nearest adjacent bump interconnect of the plurality of bump interconnects is between 20 and 30 microns.

14. The circuit package of claim 13, wherein the center-to-center pitch distance is 25 microns.

15. The circuit package of claim 1, wherein:
a first one of the first component and the second component comprises a semiconductor die; and
the second one of the first component and the second component comprises one of a semiconductor die, an interposer, and a package substrate.

16. The circuit package of claim 1, wherein the plurality of bump interconnects comprise controller collapse chip connect (C4) bumps.

17. The circuit package of claim 1, wherein the plurality of bump interconnects comprise a two-dimensional array of bump interconnects.

18. The circuit package of claim 1 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

19. A method of fabricating a circuit package, comprising:
forming a first component comprising a plurality of contact pads on a first surface;
forming a second component comprising a plurality of bump interconnects on a second surface, wherein each of the plurality of bump interconnects couples to one of the plurality of contact pads on the first surface and comprises a side surface extending in a first direction between the first surface and the second surface; and
forming a polymer layer disposed on the side surface of each of the plurality of bump interconnects and on the second surface of the second component, surrounding each of the plurality of bump interconnects.

20. The method of claim 19, further comprising:
employing thermal compression bonding to couple the plurality of bump interconnects on the second component to the plurality of contact pads on the first component.

21. The method of claim 19, wherein forming the polymer layer further comprises:
spin-coating the polymer layer onto the second surface of the second component and a side surface and an end surface of each of the plurality of bump interconnects; and
etching the polymer layer from the end surface of each of the plurality of bump interconnects.

22. A semiconductor die configured to be coupled in a circuit package, the semiconductor die comprising:
a plurality of bump interconnects on a surface of the semiconductor die, wherein:
each of the plurality of bump interconnects is configured to couple to a corresponding contact pad on a surface of a circuit component of the circuit package; and
each of the plurality of bump interconnects comprises a side surface extending from the semiconductor die; and
a polymer layer disposed on the surface of the semiconductor die and on the side surface of each of the plurality of bump interconnects, surrounding each of the plurality of bump interconnects.
